(19) United States
(12) Patent Application Publication
(10) Pub. No.: US 2026/0165208 A1
(43) Pub. Date: Jun. 11, 2026

(54) INTEGRATED CIRCUIT (IC) STRUCTURE AND FLOORPLAN THEREOF

(71) Applicant: ALCHIP TECHNOLOGIES, LIMITED, GRAND CAYMAN (KY)

(72) Inventors: WEN-HSI LIN, TAIPEI CITY (TW); KAI-TING HO, TAIPEI CITY (TW)

(21) Appl. No.: 19/377,087

(22) Filed: Nov. 3, 2025

Related U.S. Application Data
(60) Provisional application No. 63/729,588, filed on Dec. 9, 2024.

(51) Int. Cl. H01L 25/10

(52) U.S. Cl. CPC H10W 90/00

(57) ABSTRACT

The present disclosure provides an integrated circuit (IC) structure. The IC structure includes a carrier and a plurality of groups disposed over the carrier. Each of the plurality of groups includes a plurality of electronic components and having a longer side and a shorter side. The shorter side of one of the plurality of groups is aligned with the longer side of another one of the plurality of groups.

### CROSS-REFERENCE TO RELATED APPLICATION

This application claims the benefit of U.S. provisional application No. 63/729,588, filed Dec. 9, 2024, the content of which is incorporated herein by reference in its entirety.

### BACKGROUND

### 1. Technical Field

The present disclosure relates to an integrated circuit (IC) structure and a floorplan of the IC structure.

### 2. Description of the Related Art

IC structures combine various dies such as processors, memory units, interfaces, and power regulators, all integrated onto a single wafer. Existing floorplans are complex and costly, which limits competitive pricing. Therefore, efficient cell layout strategies that optimize IC performance and reliability within fixed floorplan constraints, while also improving yield, are important.

### SUMMARY

In some arrangements, an integrated circuit (IC) structure includes a carrier and a plurality of groups disposed over the carrier. Each of the plurality of groups includes a plurality of electronic components and having a longer side and a shorter side. The shorter side of one of the plurality of groups is aligned with the longer side of another one of the plurality of groups.

In some arrangements, an IC structure includes a carrier, four electronic components forming a square pattern, and four first groups of bridge elements. Each of the plurality of first group is disposed on a respective side of the square pattern.

In some arrangements, an IC structure includes a carrier, a plurality of first groups of electronic components arranged in two adjacent rows extending in a first direction, and a plurality of second groups of electronic components arranged in two adjacent columns extending in a second direction perpendicular to the first direction. A middle portion of the two adjacent rows intersects with a middle portion of the two adjacent columns.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a top view of an IC structure in accordance with some arrangements of the present disclosure.

FIG. 1B illustrates a cross-sectional view of an IC structure in accordance with some arrangements of the present disclosure.

FIG. 1C illustrates a cross-sectional view of an IC structure in accordance with some arrangements of the present disclosure.

FIG. 1D illustrates a cross-sectional view of an IC structure in accordance with some arrangements of the present disclosure.

FIG. 1E illustrates a cross-sectional view of an IC structure in accordance with some arrangements of the present disclosure.

FIG. 1F illustrates a cross-sectional view of an IC structure in accordance with some arrangements of the present disclosure.

FIG. 2 illustrates a top view of an IC structure in accordance with some arrangements of the present disclosure.

FIG. 3 illustrates a top view of an IC structure in accordance with some arrangements of the present disclosure.

### DETAILED DESCRIPTION

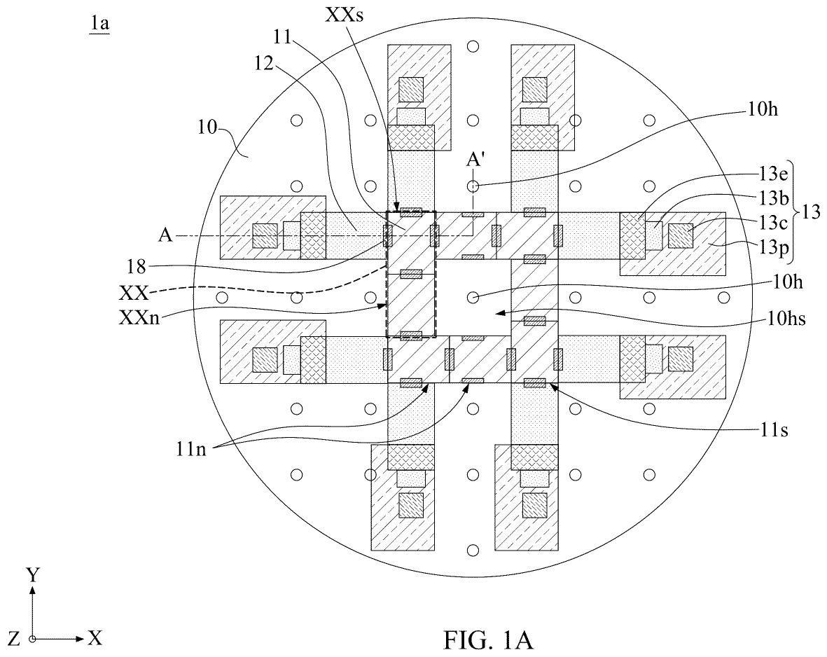

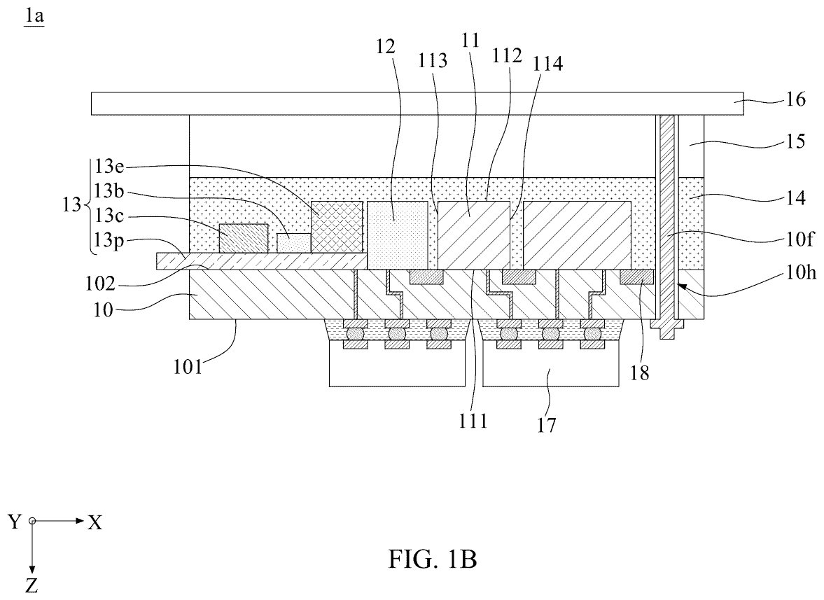

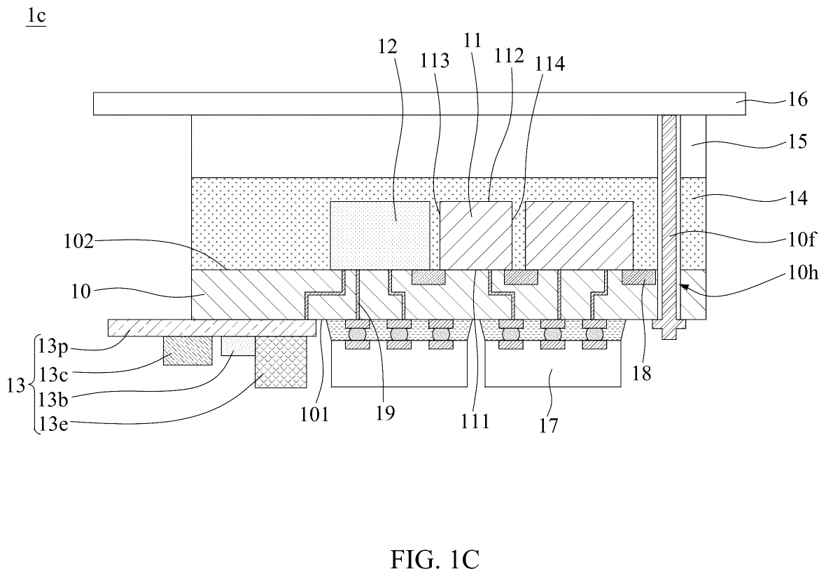

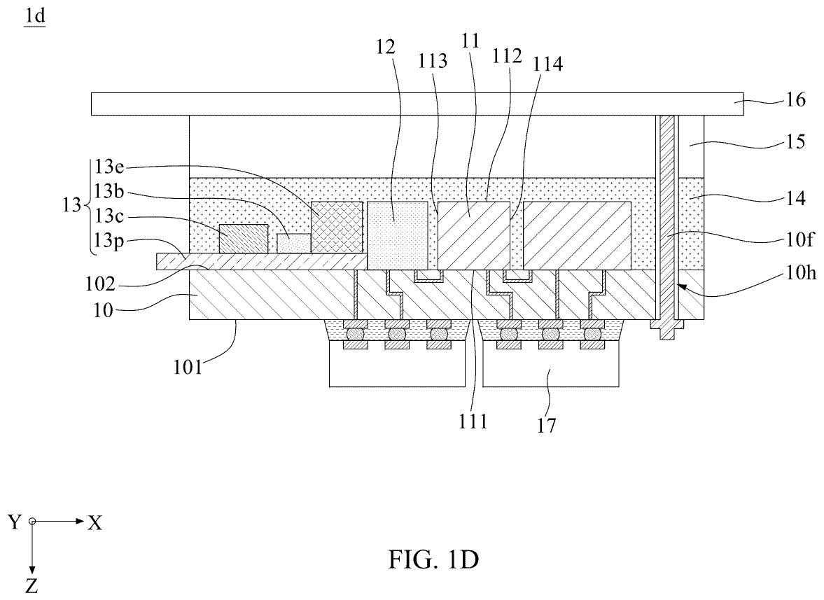

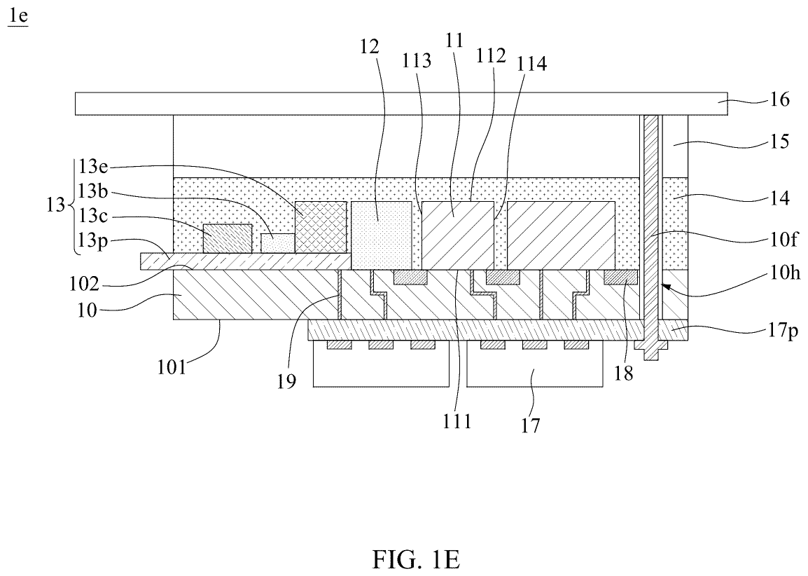

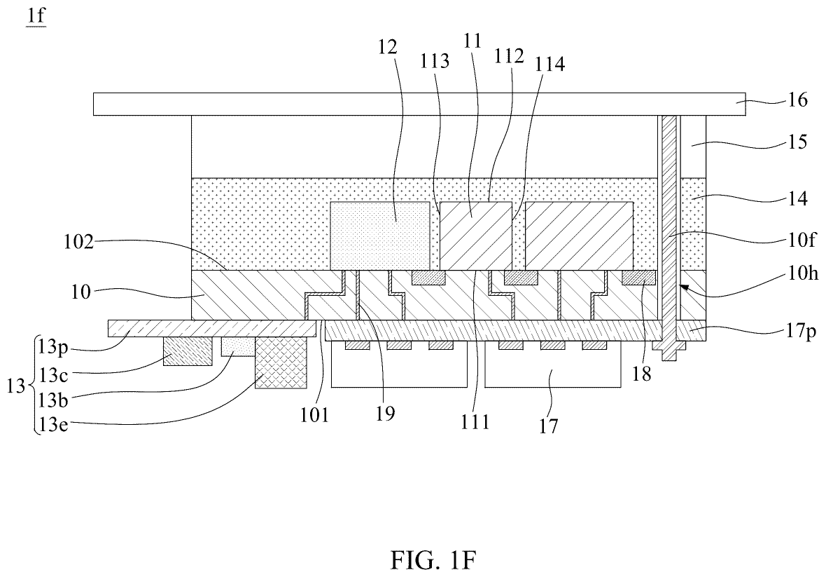

FIG. 1A illustrates a top view of an IC structure 1a in accordance with some arrangements of the present disclosure. FIG. 1B illustrates a cross-sectional view of the IC structure 1a cut through the line AA′ in FIG. 1A. The IC structure 1a may include a system on wafer (SoW). In some arrangements, the IC structure 1a may be used in applications requiring heavy data throughput, such as network routers or switch devices.

The IC structure 1a may include a carrier 10, one or more electronic components 11, one or more bridge elements 12, one or more connectors 13, and an encapsulant 14, a heat dissipating element 15, a frame 16, one or more voltage regulators 17, and one or more interposers 18. The encapsulant 14, the heat dissipating element 15, the frame 16, and the voltage regulators 17 are omitted from FIG. 1A for clarity.

The carrier 10 may include a monolithic substrate or a platform. In some arrangements, the carrier 10 may include, for example, silicon, silicon carbide, gallium nitride, gallium arsenide, aluminum nitride, or other suitable materials. In some arrangements, the carrier 10 may include a monolithic wafer or a panel. For example, the carrier 10 may be circular, rectangular, or square.

The carrier 10 may include an interconnection structure or a circuit structure 19. The circuit structure 19 may include a redistribution layer (RDL), a circuit layer, conductive pillars, conductive pads, conductive traces, conductive vias, conductive wires, or other conductive elements. The circuit structure 19 may provide electrical connections for the components connected with the carrier 10.

The carrier 10 may include a surface 101 and a surface 102 opposite to the surface 101, as shown in FIG. 1B. The carrier 10 may include one or more conductive pads in proximity to, adjacent to, or embedded in and exposed by the surface 101 and/or the surface 102. The carrier 10 may include a solder resist on the surface 101 and/or the surface 102 to fully expose or expose at least a portion of the conductive pads for electrical connections.

The electronic components 11 may be disposed over the surface 102 of the carrier 10. The electronic components 11 may be electrically connected through the circuit structure 19 embedded in the carrier 10, and the electrical connections may be attained by way of solder bonding, Cu-to-Cu bonding, wire bonding, or hybrid bonding. The electronic components 11 may be manufactured using a different process and subsequently mounted onto the carrier 10.

In some embodiments, the electronic components 11 may form a square pattern, as shown in FIG. 1A. For example, the electronic components 11 may each have a rectangular shape, with a longer side 11n and a shorter side 11s angled at 90 degrees. The square pattern may be constructed such that one side of the square pattern consists of a specific combination of these sides. For example, one side of the square pattern may be composed of one shorter side 11s and two longer sides 11n. For example, one side of the square pattern may be composed of three electronic components 11. For example, the square pattern may be formed by placing two longer sides 11n adjacent to one another, followed by one shorter side 11s, thereby completing the length of the side of the square pattern.

In some embodiments, two of the electronic components 11 may be considered as a group XX having a longer side XXn and a shorter side XXs angled at 90 degrees. For example, there may be eight electronic components 11 forming four groups XX. The groups XX may form a square pattern, as shown in FIG. 1A. For example, one side of the square pattern may be composed of one shorter side XXs and one longer side XXn. For example, one side of the square pattern may be composed of two groups XX. For example, the square pattern may be formed by placing one longer side XXn adjacent to one shorter side XXs, thereby completing the length of the side of the square pattern. In some embodiments, the length of the shorter side XXs of a group XX may be equal to that of the shorter side 11s of an electronic component 11, and the length of the shorter size XXn may be equal to twice that of the longer side 11n of the electronic component 11.

The electronic components 11 may be arranged along the X axis and the Y axis, as shown in FIG. 1A. The X axis may be referred to as the first direction, and the Y axis may be referred to as the second direction, or vice versa. The first direction may be substantially perpendicular to the second direction.

For example, the shorter side 11s of one electronic component 11 may be aligned with the longer sides 11n of two other electronic components 11 along the X axis. Similarly, the shorter side 11s of one electronic component 11 may be aligned with the longer sides 11n of two other electronic components 11 along the Y axis. For example, the shorter side XXs of one group XX may be aligned with the longer side 11n of another group XX along the X axis. Similarly, the shorter side XXs of one group XX may be aligned with the longer side XXn of another group XX along the Y axis. This systematic alignment along both axes contributes to the overall square pattern formed by the electronic components 11, ensuring a consistent and orderly layout.

The electronic components 11 may each include an integrated circuit (IC), a chip, or a die that includes a semiconductor substrate, one or more integrated circuit devices and one or more overlying interconnection structures therein. For example, the electronic components 11 may each include a controller, a processor, a central processing unit (CPU), a microprocessor unit (MPU), a graphics processing unit (GPU), a microcontroller unit (MCU), a field-programmable gate array (FPGA), a system on chip (SOC), an application specific integrated circuit (ASIC), or another type of IC.

In some arrangements, the electronic components 11 may each be connected to one or more of the interposers 18, as shown in FIG. 1A. For example, one of the electronic components 11 may be connected to four interposers 18. In some arrangements, the electronic components 11 may be communicate with one another through the interposers 18, which serves as an intermediary platform facilitating signal transmission and data exchange between the two.

The electronic components 11 may each include a surface 111 facing the carrier 10, a surface 112 opposite to the surface 111, a surface 113 extending between the surface 111 and the surface 112, and a surface 114 opposite to the surface 113, as shown in FIG. 1B. The surface 111 may be an active surface, a front surface, or a front side. The surface 112 may be a backside surface or a backside. The surfaces 113 and 114 may be sidewalls or lateral surfaces. The surfaces 113 and 114 may include the longer sides 11n, as shown in FIG. 1A.

The bridge elements 12 may be disposed over the surface 102 of the carrier 10. The bridge elements 12 may be electrically connected through the circuit structure 19 in the carrier 10, and the electrical connections may be attained by way of solder bonding, Cu-to-Cu bonding, wire bonding, or hybrid bonding. The bridge elements 12 may be manufactured using a different process and subsequently mounted onto the carrier 10.

The bridge elements 12 may be electrically connected to the electronic components 11 through the interposers 18. The bridge elements 12 may communicate with the electronic components 11 indirectly via the interposers 18, which serves as an intermediary platform facilitating signal transmission and data exchange between the two.

The bridge elements 12 may be disposed around the square pattern formed by the electronic components 11. For example, the bridge elements 12 may be disposed outside of the boundaries of the square pattern formed by the electronic components 11. For example, the bridge elements 12 may be disposed along the four sides of the square pattern formed by the electronic components 11. For example, two of the bridge elements 12 may be considered as a group disposed on one side of the square pattern formed by the electronic components 11.

For example, the bridge elements 12 may be located closer to the edge of the carrier 10 than the electronic components 11, ensuring a clear spatial separation between the bridge elements 12 and the components 11. In some arrangements, two of the bridge elements 12 may be disposed at one of the corners of the square pattern. In some arrangements, the electronic components 11 at the corners of the square pattern may be connected with four interposers 18 and two bridge elements 12, as shown in FIG. 1A.

The connectors 13 may be disposed over the periphery of the surface 102 of the carrier 10. The connectors 13 may be disposed around the square pattern formed by the electronic components 11. For example, the connectors 13 may be disposed outside of the boundaries of the square pattern formed by the electronic components 11. For example, the connectors 13 may be disposed along the four sides of the square pattern formed by the electronic components 11.

For example, the connectors 13 may be positioned closer to the edge of the carrier 10 than both the electronic components 11 and the bridge elements 12. For example, the bridge elements 12 may be arranged between the connectors 13 and the electronic components 11. For example, two of the connectors 13 may be considered as a group disposed on one side of the square pattern formed by the electronic components 11. In some arrangements, the bridge elements 12 may function as interfacing components that facilitate communication and signal transmission between the connectors 13 and the electronic components 11.

The connectors 13 may be electrically connected through the circuit structure 19 in the carrier 10, and the electrical connections may be attained by way of solder bonding, Cu-to-Cu bonding, wire bonding, or hybrid bonding. The connectors 13 and the electronic components 11 may be disposed on the same side of the carrier 10, as shown in FIG. 1B, to simplify vias and through-hole connections, potentially decreasing parasitic inductance/capacitance and improving signal integrity.

The connectors 13 may be configured to provide external connections, enabling communication and power transfer between the IC structure 1a and external devices or systems. For instance, the connecting element 13c can establish electrical pathways that link the IC structure 1a to peripheral components, circuit boards, or other modules within an electronic assembly.

The connectors 13 may each include several components, including a printed circuit board (PCB) 13p, one or more network chips 13e, one or more electrical contacts 13b, and one or more connecting elements 13c. The PCB 13p may facilitate signal routing and mechanical support. The network chips 13e may handle data processing and communication functions within the connector 13, such as signal conditioning, protocol handling, or network interfacing. In some arrangements, the network chips 13e may be omitted.

In some arrangements, the electrical contacts 13b may include solder balls or solder bumps, such as controlled collapse chip connection (C4) bumps, a ball grid array (BGA) or a land grid array (LGA). In some arrangements, the connecting elements 13c may include conductive pillars, solder balls, conductive wires, board-to-board connectors, connectors suitable for Hot Bar soldering techniques, or combinations thereof. Additionally, other feasible connector types may be employed depending on the specific application requirements, manufacturing processes, and performance criteria.

In some arrangements, placing the bridge elements 12 and connectors 13 at the periphery of the array in the IC structure 10a may help isolate them from noisy switching activity in the core logic, thereby improving signal integrity. In addition, the bridge elements 12 and connectors 13 at the periphery can be designed as modular units, making it easier to scale connector size by adding or removing peripheral blocks without disturbing the core logic.

It should be noted that although eight electronic components 11, eight bridge elements 12, and eight connectors 13 are illustrated in FIG. 1A as an example, the scope is not limited to these specific quantities. In various arrangements, the number, relative positioning, absolute location, and orientation of the components may be selected or adjusted according to the specific design requirements or functional objectives.

As illustrated in FIG. 1B, the encapsulant 14 may be disposed over the surface 102 of the carrier 10. The encapsulant 14 may cover, surround, or encapsulate the electronic components 11 and the bridge elements 12. The encapsulant 14 may cover, surround, or encapsulate the surface 112, the surface 113, and the surface 114 of the electronic component 11. The encapsulant 14 may separate the electronic component 11 from other components, such as the bridge element 12 adjacent to the electronic component 11 or another electronic component 11. The encapsulant 14 may separate the bridge element 12 from other components, such as the electronic component 11 adjacent to the bridge element 12 or another bridge element 12. The encapsulant 14 may at least partially cover, surround, or encapsulate the connectors 13. For example, the encapsulant 14 may cover, surround, or encapsulate the PCB 13p, the more network chip 13e, the electrical contact 13b, and/or the connecting elements 13c. The encapsulant 14 may expose or uncover at least a part of the connectors 13. For example, the PCB 13p, the more network chip 13e, the electrical contact 13b, and/or the connecting elements 13c may be exposed.

The encapsulant 14 may include an epoxy resin with fillers, a molding compound (e.g., an epoxy molding compound or another type of molding compound), a polyimide, a phenolic compound or material, a material with a silicone dispersed therein, or a combination thereof.

The heat dissipating element 15 may be disposed over the encapsulant 14. In some arrangements, the heat dissipating element 15 may be connected to a surface of the encapsulant 14 through an adhesive layer, such as a heat dissipating gel. In some arrangements, in a direction substantially perpendicular to the surface 101 and/or the surface 102 of the carrier 10 (such as along the Z axis), the electronic component 11 and the heat dissipating element 15 may be at least partially overlapped to facilitate heat dissipation for the electronic component 11.

In some arrangements, in a direction substantially perpendicular to the surface 101 and/or the surface 102 of the carrier 10 (such as along the Z axis), the bridge element 12 and the heat dissipating element 15 may be at least partially overlapped to facilitate heat dissipation for the bridge element 12.

The heat dissipating element 15 may include a relatively high thermal conductivity. For example, the heat dissipating element 15 may include copper (Cu), aluminum (Al), graphite, ceramics, etc. The heat dissipating element 15 may include a block, a pipe, a sink, a fin, or other shapes.

The carrier 10, the encapsulant 14, and the heat dissipating element 15 may together define a hole 10h. From the top view in FIG. 1A, multiple holes 10h may be arranged in a row, or along the X axis. Multiple holes 10h may be arranged in a column, or along the Y axis. Multiple holes 10h may be arranged in an array, a grid, or an ordered series or arrangement. One of the holes 10h may be arranged in the square pattern formed by the electronic components 11. For example, the electronic components 11 may define a space 10hs (e.g., a smaller square pattern or a squared space) at the center of their configuration, and one of the holes 10h may be positioned in the space 10hs. The hole 10h may be surrounded by the electronic components 11. The electronic components 11 may enclose the hole 10h. In other words, the hole 10h may be disposed within the squared space 10hs defined by the square pattern formed by the electronic components 11.

The hole 10h may penetrate or extend through the carrier 10, the encapsulant 14, and the heat dissipating element 15. The hole 10h may be a continuous passage in the carrier 10, the encapsulant 14, and the heat dissipating element 15. A fixing element 10f may be disposed in the hole 10h. The hole 10h may be configured to accommodate the fixing element 10f.

The frame 16 may be disposed over the heat dissipating element 15. The frame 16 may be a bracket or a rest. The frame 16 may be configured to provide structural support for the IC structure 1a. The fixing element 10f may secure the carrier 10, the encapsulant 14, and the heat dissipating element 15 to the frame 16. The frame 16 and the fixing element 10f may be configured to hold or reinforce the IC structure 1a attached to another surface.

For example, the frame 16 and the fixing element 10f may be or include a mechanical or magnetic means to resist or arrest the movement of the IC structure 1a. The mechanical or magnetic means may prevent unintended separation of the IC structure 1a. For example, the frame 16 may have a thread that corresponds to the fixing element 10f, which may be a screw. In some other arrangements, the mechanical or magnetic means may include a pin, a post, a spring, a plugger, a buffer, a snap, a clip, a contour, etc.

The voltage regulators 17 may be disposed over the surface 101 of the carrier 10. The voltage regulators 17 may be electrically connected through the circuit structure 19 in the carrier 10, and the electrical connections may be attained by way of solder bonding, Cu-to-Cu bonding, wire bonding, or hybrid bonding.

The voltage regulators 17 may each include a linear regulator (configured to maintain a constant output voltage) or a switching regulator (configured to generate an output voltage that is higher or lower than the input voltage). In some arrangements, the voltage regulators 17 may each include a step-down (buck) converter, a step-up (boost) converter, an analog-to-digital converter, a digital-to-analog converter, an AC-DC converter, a DC-DC converter, other types of converters, or a combination thereof.

In some arrangements, the voltage regulators 17 may each include a power management integrated circuit (PMIC) (not shown). The voltage regulators 17 may each be configured to provide different types of power control to different parts of the IC structure 1a. For example, the voltage regulators 17 may each be configured to provide regulated power to the electronic components 11. For example, the voltage regulators 17 may each be configured to provide different output voltages to the electronic components 11.

It should be noted that the positions and number of the voltage regulators 17 in the IC structure 1a are not intended to limit the present disclosure. For example, the number of voltage regulators 17 in the IC structure 1a may vary depending on design requirements.

Referring to FIG. 1B, the interposers 18 may be disposed or embedded in the carrier 10. The interposers 18 may be at least partially exposed from the carrier 10. The interposers 18 may be at least partially disposed on the surface 102 of the carrier 10.

The interposers 18 may have a relatively higher density or a relatively finer pitch wiring layer than the carrier 10. The interposers 18 may help reduce signal delay, noise, and crosstalk. In addition, the interposers 18 may be configured to mix and match different memory capacities and types with the same electronic component, allowing for greater flexibility in the production workflow and enabling the integration of components that require specialized optimization techniques before assembly.

FIG. 1C illustrates a cross-sectional view of an IC structure 1c in accordance with some arrangements of the present disclosure. In some arrangements, the IC structure 1a cut through the line AA′ in FIG. 1A may have a cross-sectional view as shown in FIG. 1C. The IC structure 1c shown in FIG. 1C is similar to the IC structure 1a shown in FIG. 1B except that the connectors 13 shown in FIG. 1C are disposed over the periphery of the surface 101 of the carrier 10.

Referring to FIG. 1C, the connectors 13 and the electronic components 11 are respectively disposed on surfaces 101 and 102 of the carrier 10 to reduce electromagnetic interference (EMI) and crosstalk between high-speed signals and connector contacts. In addition, the connectors 13 on the opposite side do not obstruct airflow or heat dissipation and allow easy access for cable connections during assembly and testing without disturbing the chip side.

FIG. 1D illustrates a cross-sectional view of an IC structure 1d in accordance with some arrangements of the present disclosure. In some arrangements, the IC structure 1a cut through the line AA′ in FIG. 1A may have a cross-sectional view as shown in FIG. 1D. The IC structure 1d shown in FIG. 1D is similar to the IC structure 1a shown in FIG. 1B except that the interposers 18 may be omitted.

Referring to FIG. 1D, the electronic components 11 and the bridge elements 12 may communicate via the circuit structure 19 embedded in the carrier 10. This configuration potentially simplifies the overall design by eliminating the need for interposers, which can reduce manufacturing complexity and cost.

FIG. 1E illustrates a cross-sectional view of an IC structure 1e in accordance with some arrangements of the present disclosure. In some arrangements, the IC structure 1a cut through the line AA′ in FIG. 1A may have a cross-sectional view as shown in FIG. 1E. The IC structure 1e shown in FIG. 1E is similar to the IC structure 1a shown in FIG. 1B except that the voltage regulators 17 are connected to the carrier 10 through a printed circuit board (PCB) 17p. The fixing element 10f may penetrate or extend through the PCB 17p. The fixing element 10f may secure the PCB 17p to the frame 16. In some arrangements, the PCB 17p may include copper traces and pads designed to enable the voltage regulators 17 to connect to the carrier 10 with varying circuit densities and accommodate different electrical requirements.

FIG. 1F illustrates a cross-sectional view of an IC structure 1f in accordance with some arrangements of the present disclosure. In some arrangements, the IC structure 1a cut through the line AA′ in FIG. 1A may have a cross-sectional view as shown in FIG. 1F. The IC structure 1f shown in FIG. 1F is similar to the IC structure 1c shown in FIG. 1C except that the voltage regulators 17 are connected to the carrier 10 through the PCB 17p. The number and the size of the PCB 17p can be adjusted according to the different electrical requirements.

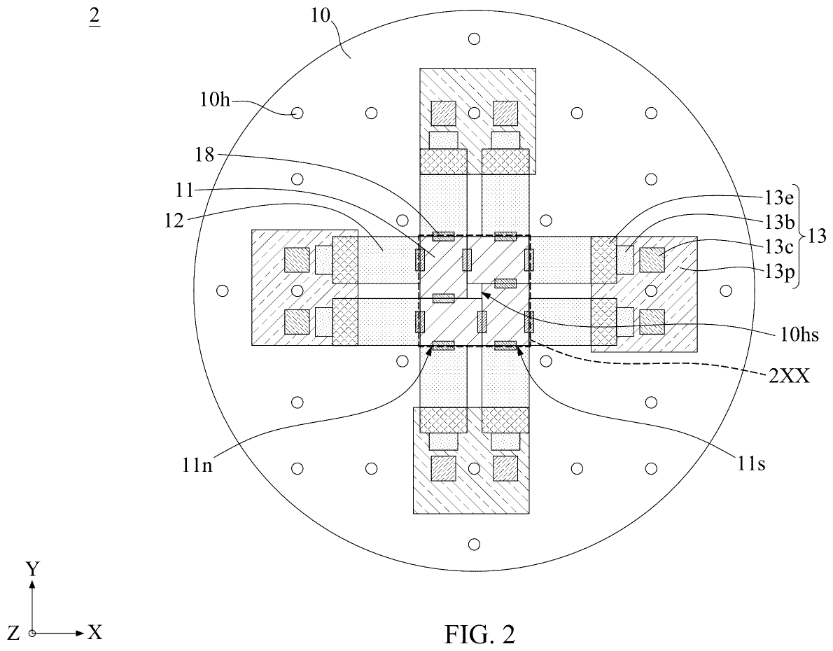

FIG. 2 illustrates a cross-sectional view of an IC structure 2 in accordance with some arrangements of the present disclosure. The IC structure 2 shown in FIG. 2 is similar to the IC structure 1a shown in FIG. 1A except the following differences apply.

Referring to FIG. 2, four electronic components 11 may be collectively referred to as a block or a group 2XX. In the group 2XX, four electronic components 11 may form a square pattern. One side of the square pattern may be composed of one shorter side 11s of one electronic component 11 and one longer side 11n of another electronic component 11.

For example, the shorter side 11s of one electronic component 11 may be aligned with the longer side 11n of another electronic component 11 along the X axis. Similarly, the shorter side 11s of one electronic component 11 may be aligned with the longer side 11n of another electronic component 11 along the Y axis.

The four electronic components 11 may define a space 10hs (e.g., a smaller square pattern or a squared space) at the center of their configuration, and there is no hole positioned within the space 10hs, as shown in FIG. 2. Each of the electronic components 11 may be connected to four interposers 18, as shown in FIG. 2. This arrangement allows for efficient use of space and may facilitate specific functional or structural requirements in the overall design.

Two of the connectors 13 may be considered as a group disposed on one side of the square pattern formed by the electronic components 11. Two of the connectors 13 may share the same PCB 13p. Two of the bridge elements 12 may be considered as a group and connecting between one of the PCBs 13p and one side of the square pattern formed by the electronic components 11.

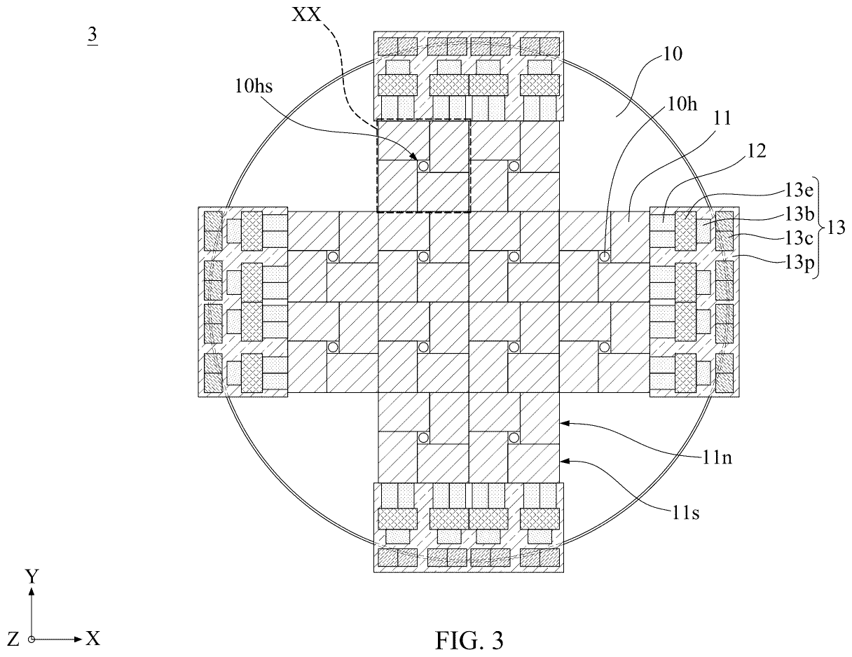

FIG. 3 illustrates a cross-sectional view of an IC structure 3 in accordance with some arrangements of the present disclosure. The IC structure 3 shown in FIG. 3 is similar to the IC structure 2 shown in FIG. 2 except the following differences apply.

Referring to FIG. 3, a portion (or a first group) of the electronic components 11 may be arranged in two adjacent columns along the Y axis and another portion (or a second group) of the electronic components 11 may be arranged in two adjacent rows along the X axis. The middle portion of the two adjacent rows may intersect with the middle portion of the two adjacent columns.

In some arrangements, the shorter sides 11s and the longer sides 11n of the electronic components 11 may be disposed alternately in the two adjacent rows. Similarly, the shorter sides 11s and the longer sides 11n of the electronic components 11 may be disposed alternately in the two adjacent columns. This indicates that the orientations of one electronic component 11 and its neighboring electronic component 11 may have an angle difference of 90 degrees along the X axis or the Y axis.

In some arrangements, a plurality of groups XX may be arranged along an X-Y plane. The groups XX may be arranged in an array, a grid, or any other ordered series or systematic arrangement. For example, the groups XX may be arranged in a cross-shaped pattern. For example, the groups XX may include two vertical lines (or two adjacent columns) along the Y axis and two horizontal lines (or two adjacent rows) along the X axis, and the vertical lines intersect the horizontal lines at their midpoints. This indicates four groups XX are within the intersect portion of two vertical lines and two horizontal lines formed by the groups XX. This arrangement allows for balanced distribution and can be useful in applications requiring central alignment or intersection-based referencing.

Four of the connectors 13 may be considered as a group disposed on one side of the cross-shaped pattern formed by the electronic components 11. Four of the connectors 13 may share the same PCB 13p. Eight of the bridge elements 12 may be considered as a group and connecting between one of the PCBs 13p and one side of the cross-shaped pattern formed by the electronic components 11. This configuration enables efficient, reliable signal transmission between the electronic components 11 and the connectors 13 within the IC structure 3.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amount, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An integrated circuit (IC) structure, comprising:
a carrier; and
a plurality of groups disposed over the carrier, each group including a plurality of electronic components and having a longer side and a shorter side,
wherein the shorter side of one of the plurality of groups is aligned with the longer side of another one of the plurality of groups.

2. The IC structure of claim 1, wherein the plurality of groups form a square pattern.

3. The IC structure of claim 2, wherein a side of the square pattern is composed of three of the plurality of electronic components.

4. The IC structure of claim 2, wherein the carrier defines a hole configured to accommodate a fixing element to hold the IC structure to another surface, and wherein the hole is disposed within a squared space defined by the square pattern.

5. The IC structure of claim 1, wherein one shorter side and one longer side of the plurality of groups are aligned along a first direction and a second direction substantially perpendicular to the first direction.

6. The IC structure of claim 1, wherein one of the plurality of electronic components is connected with four interposers and two bridge elements.

7. The IC structure of claim 1, wherein the carrier comprises a monolithic wafer or a monolithic panel.

8. The IC structure of claim 1, further comprising:
an encapsulant disposed over a first surface of the carrier and covering the plurality of electronic components.

9. The IC structure of claim 8, further comprising:
a connector disposed over the first surface of the carrier and at least partially covered by the encapsulant.

10. The IC structure of claim 9, further comprising:
a voltage regulator disposed over a second surface of the carrier opposite to the first surface.

11. The IC structure of claim 8, further comprising:
a connector disposed over a second surface of the carrier opposite to the first surface.

12. An IC structure, comprising:
a carrier;
four electronic components forming a square pattern; and
four first groups of bridge elements, each first group disposed on a respective side of the square pattern.

13. The IC structure of claim 12, wherein each of the four electronic components has a longer side and a shorter side, and a side of the square pattern is composed of one shorter side and one longer side of the four electronic components.

14. The IC structure of claim 12, further comprising:
four second groups of connectors, each second group disposed on the respective side of the square pattern.

15. The IC structure of claim 14, wherein one of the first groups of bridge elements is connected between a corresponding one of the second groups of connectors.

16. The IC structure of claim 12, further comprising:
a plurality of interposers embedded in the carrier.

17. The IC structure of claim 16, wherein each of the four electronic components is connected with four of the plurality of interposers.

18. An IC structure, comprising:
a carrier;
a plurality of first groups of electronic components arranged in two adjacent rows extending in a first direction; and
a plurality of second groups of electronic components arranged in two adjacent columns extending in a second direction perpendicular to the first direction,
wherein a middle portion of the two adjacent rows intersects with a middle portion of the two adjacent columns.

19. The IC structure of claim 18, wherein shorter sides and longer sides of the electronic components within the plurality of first groups are disposed alternately in the two adjacent rows.

20. The IC structure of claim 19, wherein shorter sides and longer sides of the electronic components within the plurality of second groups are disposed alternately in the two adjacent columns.
